(19) United States
(12) Patent Application Publication
(10) Pub. No.: US 2007/0241346 A1
(43) Pub. Date: Oct. 18, 2007

(54) Light emitting device and method for producing light emitting device

(75) Inventors: Masahiro Konishi, Ikoma-shi (JP); Yuhsuke Fujita, Higashihiroshima-shi (JP); Toshiyuki Takada, Kashihara-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/783,709

(22) Filed: Apr. 11, 2007

(30) Foreign Application Priority Data
Apr. 13, 2006 (JP) 2006-111292

(51) Int. Cl. H01L 33/00

(52) U.S. Cl. 257/81

(57) ABSTRACT

A light emitting device of the present invention includes: a substrate including wire patterns separated from each other on a basic material and a runner section to which sealing resin is poured, which runner section is a space between the wire patterns; a light emitting element die-bonded on the substrate; and a resin section in which the light emitting element is sealed using the sealing resin poured via the runner section.

This non-provisional application claims priority under 35 U.S.C. §119(a) on Patent Application No. 11129.2/2006 filed in Japan on Apr. 13, 2006, the entire contents of which are hereby incorporated by reference.

### FIELD OF THE INVENTION

The present invention relates to a light emitting device and a method for producing the light emitting device.

### BACKGROUND OF THE INVENTION

Recently, surface-mount light emitting devices including light emitting diode chips (hereinafter referred to as a “chip”) have been widely used as auxiliary light sources for cameras included in portable phones.

Light emitted from a chip itself does not have directivity. Therefore, in order to obtain intense light over an area captured by a camera, it is necessary to converge light emitted from the chip so that the light has predetermined radiation characteristics with an optical axis of the light emitting device being a center. For that reason, there is provided a light emitting device which separately includes a lens and a reflector for providing directivity in an optical axis direction and for increasing luminance by reflection. Such light emitting device is disclosed in Japanese Unexamined Patent Publication No. 327955/2004 (Tokukai 2004-327955; published on Nov. 18, 2004) for example.

Further, the light emitting device is capable of emitting white light by mixing phosphor in a chip and sealing resin which seals the chip. The phosphor is excited by light emitted from the chip and thus radiates light having different wavelengths.

Potting has been performed as a method for sealing a chip.

With reference to FIG. 8, the following explains a conventional method for producing a light emitting device. FIGS. 8(a) to 8(d) are a plan drawing and cross sectional drawings each showing a method for producing a light emitting device. FIG. 8(e) is an oblique drawing showing a light emitting device 315.

On a substrate 301, plural sets of wire patterns 302 including a wire pattern 302a and a wire pattern 302b which are separated from each other are serially provided on a main plane 312 of a basic material 301a so as to extend in a one direction. A chip 3 is die-bonded on the wire pattern 302a. Then, an electrode of the chip 3 is wire-bonded with the wire pattern 302b via a wire 4. A through hole 9 serving as an external terminal is formed at a predetermined position of the substrate 301. A conductor is formed on the inside wall of the through hole 9 via plating and the conductor is conducted with an electrode pattern formed on a side opposite to a side on which the chip 3 is mounted.

A dam sheet 330 is a thin plate made of silicone rubber or other material. The dam sheet 330 has a hollow section 316 having a cylinder shape so that the hollow section 316 corresponds to a position of the chip 3 which is die-bonded on the wire pattern 302a. The dam sheet 330 is placed on and attached to the main plane 312 so that the position of the chip 3 and the position of the hollow section 316 correspond to each other.

Sealing resin 8 is dropped from an upper opening of the hollow section 316 by a dispenser 25, thereby forming a resin section 310 in which the chip 3 and the wire 4 are sealed. At that time, if the sealing resin 8 includes bubbles, the light emitting device 315 has disturbed radiation characteristics and is defective. For that reason, the sealing resin 8 is left for some time without any treatment so that the sealing resin 8 is degassed. Thereafter, the sealing resin 8 is subjected to a thermal-cure process.

When the wire patterns 302 formed on a surface of the substrate 301 have uneven surfaces, there is a possibility that the sealing resin 8 leaks from a surface on which the dam sheet 330 is placed. In order to prevent such a leakage, resist having a pattern in accordance with the surface on which the dam sheet 330 is placed may be applied on the main plane 312.

Further, it is desirable that the sealing resin 8 has high transmittance with respect to a wavelength of light emitted by the light emitting device 315. An example of the sealing resin 8 is light-transmitting resin such as silicone.

Further, it is possible to obtain white light by mixing phosphor in the sealing resin 8. The phosphor is excited by light from the chip 3 and radiates light having different wavelengths.

Subsequently, the substrate 301 is separated from the dam sheet 330, and heated in an oven so that the substrate 301 is subjected to an after-cure process.

A reflector 13 is a thin plate having a hole 14 so that the hole 14 corresponds to a position of the resin section 310 formed on the main plane 312. The vertical cross section of the hole 14 has a mortar shape. The inside of the hole 14 is preferably a reflective surface which increases a reflective efficiency. The reflector 13 is attached to the main plane 312 so that the position of the resin section 310 and the position of the hole 14 correspond to each other. While the reflector 13 is attached to the main plane 312, the reflector 13 surrounds a peripheral part of the resin section 310 at a bottom of the hole 14, allowing light from the chip 3 to be reflected forward.

Lastly, while the reflector 13 is attached to the main plane 312, the substrate 301 is diced at a predetermined position (e.g. a dotted line). As a result, the light emitting device 315 is provided.

With the method, the resin section 310 has a cylindrical shape and light is mainly emitted from a top surface. Further, the height of the resin section 310 depends on the amount of the dropped sealing resin 8.

However, with the conventional method, the amount of dropped sealing resin and the amount of a hollow section in a dam sheet vary, resulting in variation in the height of the resin section 310. Further, when the sealing resin 8 is subjected to a thermal-cure process, the upper surface of the resin section 310 slightly caves in. Consequently, it is difficult to produce the resin sections 310 having substantially identical shape. Further, as the upper surface of the resin section 310 is substantially flat, it is impossible to cause a lens disclosed in Japanese Unexamined Patent Publication No. 327955/2004 (Tokukai 2004-327955; published on Nov. 18, 2004) to be formed integrally with the resin section 310.

On the other hand, it is possible to cause the resin section 310 to have a lens shape when the resin section 310 is produced, by using a mold which includes: a cavity corresponding to the shape of the resin section 310; and a runner section for guiding the sealing resin 8 to the cavity. At that time, the sealing resin 8 flows in the runner section of the mold and is cured to be a runner, which protrudes from a side of the resin section 310 and is connected with an adjacent resin section. The runner is seen as a swelling on the main plane 312. Consequently, when the reflector 13 is attached to the main plane 312, a space is provided between the reflector 13 and the main plane 312. As a result, when the substrate 301 is diced, the reflector 13 is likely to be inclined.

Even when the runner is removed, a trace where the runner is removed remains. There is a possibility that light leaks from the trace or radiation characteristics of light are disturbed.

Further, in order that bubbles are not generated in the resin section 310, it is necessary to pour, with high pressure, the sealing resin 8 into the mold that has been sealed. This requires large-scale equipment.

### SUMMARY OF THE INVENTION

In view of the foregoing problems, an object of the present invention is to provide (i) a method for producing a light emitting device, allowing for forming a runner in a space between wire patterns separated from each other, and (ii) a light emitting device produced by the method.

In order to achieve the foregoing object, a light emitting device of the present invention includes: a substrate, including (i) wire patterns separated from each other on a main plane of a basic material, and (ii) a runner made of resin, provided in a space between the wire patterns; and a light emitting element, die-bonded on the substrate, the light emitting element being sealed by the resin constituting the runner.

Further, in order to achieve the foregoing object, a method of the present invention for producing a light emitting device includes the steps of: (I) attaching a substrate to a mold which includes a cavity section, a resin pouring port connected with the cavity section, and an air vent open to air, said substrate including, on a main plane thereof, (i) a light emitting element die-bonded on the main plane, (ii) wire patterns separated from each other, and (iii) a runner section to which resin is poured, which runner section is a space between the wire patterns; and (II) pouring resin into the cavity section using the runner section as a path via which the resin flows.

Further, in order to achieve the foregoing object, a substrate of the present invention, on which substrate a light emitting element is to be mounted, includes: wire patterns separated from each other on a surface of a basic material; and a runner section to which resin is poured, said runner section being a space between the wire patterns.

In the light emitting device of the present invention, a space between the wire patterns and a thickness of each wire pattern constitute the runner section having a groove shape, and sealing resin is caused to fill the runner section so as to be a runner. Consequently, the runner does not remain on a side of the resin section. As a result, the main plane is formed evenly, and therefore it is easy to provide a reflector on the main plane. Further, the sealing resin is caused to fill the runner section so as to be a runner and the runner does not need to be removed. Therefore, it is possible to prevent problems in the conventional technique, such as a leakage of light from a part where a runner has been removed and disturbance of radiation characteristics.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is a process drawing showing a method for producing a light emitting device of an embodiment of the present invention.

FIG. 2(a) is a plan drawing showing a substrate to which a chip is die-bonded. FIGS. 2(b) and 2(c) are cross sectional drawings each showing a substrate to which a chip is die-bonded. The chip is die-bonded to the substrate with wire-bonding completed.

FIG. 3(a) is an oblique drawing showing a structure of a mold. FIGS. 3(b) and 3(c) are cross sectional drawings each showing a substrate which is set to the mold and to which resin is poured and molded.

FIG. 4(a) is a plan drawing showing a substrate to which a reflector is attached. FIG. 4(b) is a cross sectional drawing showing a substrate to which a reflector is attached. FIGS. 4(c) and 4(d) are oblique drawings each showing a light emitting element having been diced.

FIGS. 5(a) and 5(b) are plan drawings each showing a substrate in which wire patterns are formed so that four chips are sealed in one resin section.

FIG. 6(a) is a graph showing radiation characteristics of a light emitting device of the present invention. FIG. 6(b) is a graph showing radiation characteristics of a conventional light emitting device.

FIG. 7 is an oblique drawing showing a structure of a cavity mold in which a large number of cavities are provided.

FIGS. 8(a) to 8(e) are process drawings showing a method for producing a conventional light emitting device.

### DESCRIPTION OF THE EMBODIMENTS

The following explains an embodiment of the present invention with reference to drawings.

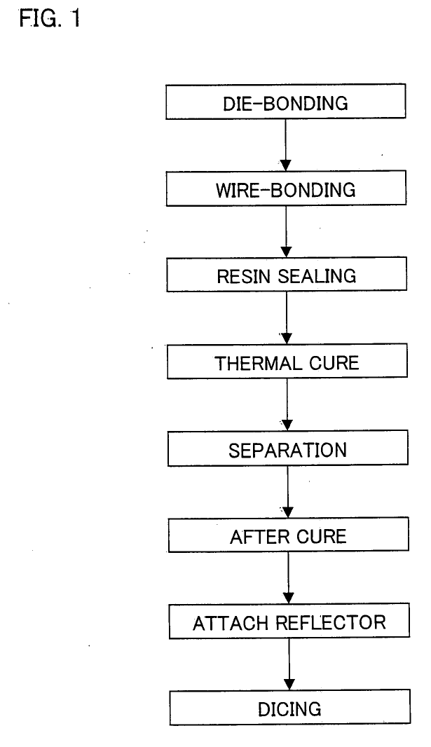

FIG. 1 is a process drawing showing a method for producing a light emitting device of an embodiment of the present invention.

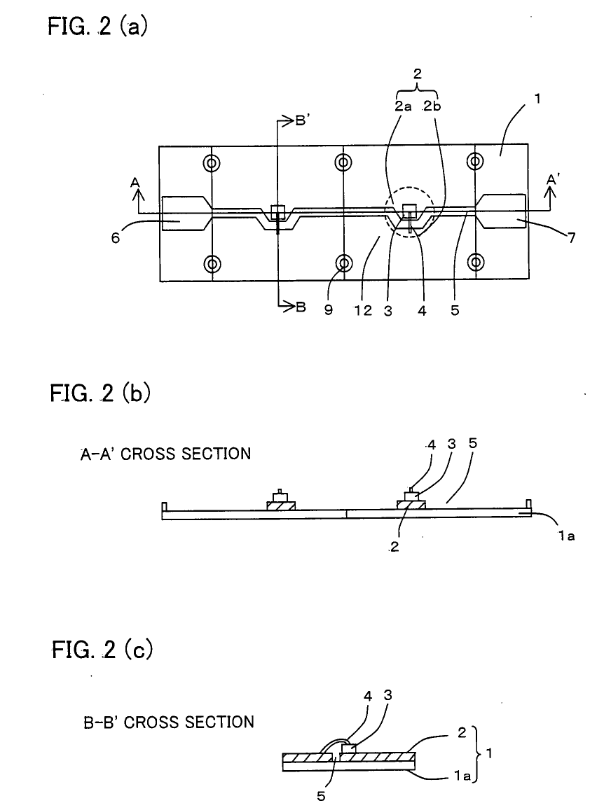

FIGS. 2(a) to 2(c) are a plan drawing and cross sectional drawings each showing a substrate to which a chip is die-bonded and wire-bonded. In a substrate 1, plural sets of wire patterns 2 including a wire pattern 2a and a wire pattern 2b which are separated from each other are serially provided on a main plane 12 of a basic material 1a having a plate shape so that the wire patterns 2 extend in one direction.

The wire pattern 2a and the wire pattern 2b are formed by pressing, on the basic material, a copper foil whose thickness is 70 μm. As mentioned later, a space between the wire pattern 2a and the wire pattern 2b serves as a runner section 5 having a groove shape. The runner section 5 guides a flow of sealing resin 8. A width of the space is 150 μm for example.

A through hole 9 serving as an external terminal is formed on a predetermined position of the substrate 1. A conductor is formed on an inside wall of the through hole 9 via plating, and the conductor is conducted with an electrode pattern formed on a side opposite to a side on which a chip is mounted.

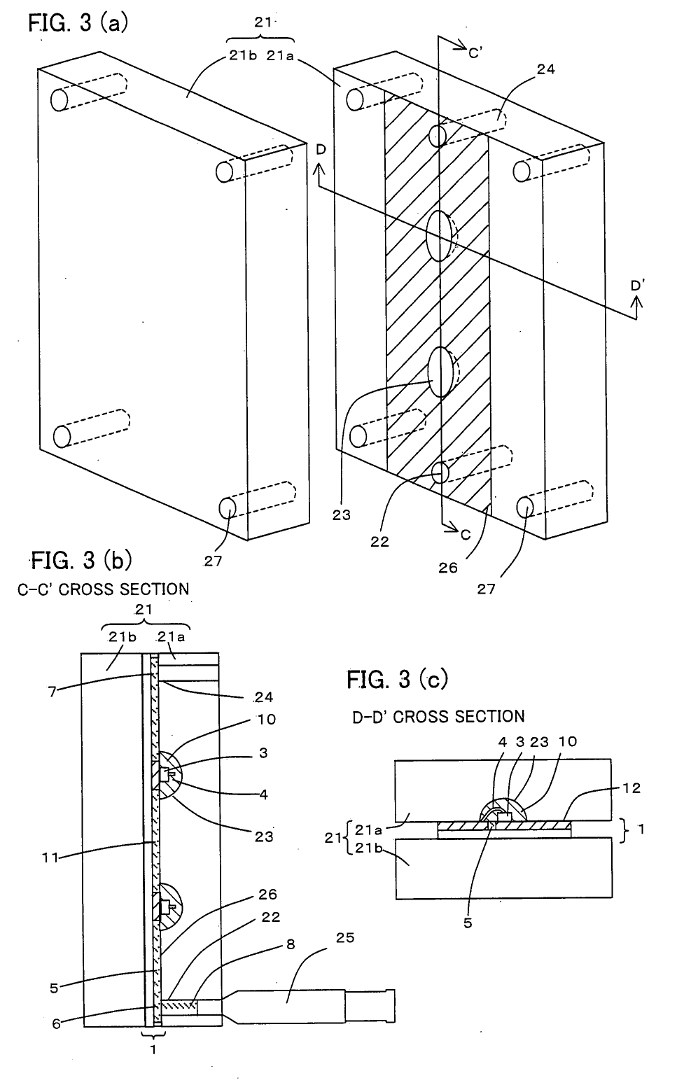

FIG. 3(a) is an oblique drawing showing a structure of a mold. FIGS. 3(b) and 3(c) are cross sectional drawings each showing a substrate set to the mold. A mold 21 includes a cavity mold 21a and a base mold 21b. The cavity mold 21a includes a set surface 26 on which the substrate 1 is to be set. In the set surface 26, a resin pouring port 22 via which the sealing resin 8 for sealing a chip 3 is poured, a cavity 23 for forming a resin section 10 (mentioned later) in which the resin 3 is sealed, and an air vent 24 via which air in the cavity 23 is degassed so that the sealing resin 8 fills the cavity 23 easily are provided in this order in one direction. The cavity 23 is provided so as to correspond to the position of the chip 3 which is die-bonded on the wire pattern 2a. Further, the cavity 23 is formed in a surface of the set surface 26 so as to have a hemisphere shape, allowing the resin section 10 to have a lens shape. For example, the cavity 23 is formed so that the diameter is Φ=2 mm and the radius of curvature of the hemisphere is R=1.5 mm.

A surface of the substrate 1 on which surface the chip is mounted is attached to the set surface 26, and the substrate 1 is set between the cavity mold 21a and the base mold 21b and is clamped. At that time, the position of the chip 3 corresponds to the position of the cavity 23, the position of a pouring gate 6 corresponds to the position of the resin pouring port 22, and the position of an exhausting gate 7 corresponds to the position of the air bent 24. Consequently, the chip 3 is inserted in the cavity 23. While the chip 3 is inserted in the cavity 23, a surface of the runner section 5 having a groove shape is sealed by the set surface 26. Consequently, a path via which the sealing resin 8 is guided to the cavity 23 is formed so as to have a pipe shape.

Subsequently, the mold 21 which clamps the substrate 1 is inclined vertically, and the sealing resin 8 is poured via the resin pouring port 22, thereby forming the resin section 10 in which the chip 3 die-bonded on the substrate 1 and the wire 4 are sealed. The sealing resin 8 flows in the runner section 5 from an opening to the cavity 23 into the cavity 23 and fills the cavity 23. Consequently, the resin section 10 is formed so as to have a lens shape, and the sealing resin 8 filling the runner section 5 becomes a runner 11. At that time, it is imperative to turn the mold 21 so that the resin pouring port 22 faces downward, and to quietly pour the sealing resin 8 so that bubbles are not generated.

The air vent 24 is open to air and therefore pressure of the sealing resin 8 pouring into the cavity 23 is low. Consequently, only small power is required for claming. The claming may be a simple one such as bolting bolt holes 27 provided at corners of the mold 21.

With the method, the surfaces of the wire patterns 2 and the surface of the runner 11 on the main plane 12 have the same surface level at their border, making it easy to attach the reflector 13 (mentioned later) on the main plane 12.

To be specific, for example, an end of a pouring port of a dispenser 25 containing the sealing resin 8 is inserted into the resin pouring port 22, and the sealing resin 8 is poured with a pressure similar to that of a piston pushed by a finger, so that the sealing resin 8 flows via the runner section 5 approximately at a speed of 1 cm/sec.

It is desirable that the sealing resin 8 has high transmittance with respect to a wavelength of light emitted by a light emitting device 15 and is a liquid with low viscosity. A preferable example of the sealing resin 8 is silicone.

The mold 21 is not necessarily to be inclined vertically. The mold 21 may be inclined so that an exhausting port of the runner section 5 is positioned higher enough than a pouring port of the runner section 5 to prevent generation of bubbles in the cavity 23.

It is possible to obtain white light by mixing phosphor in the sealing resin 8. The phosphor is excited by light from the chip 3 and radiates light having different wavelengths.

Further, after the sealing resin 8 fills the cavity 23, the mold 21 may be turned so that the runner section 5 is positioned horizontally, allowing the phosphor to sediment evenly with respect to the optical axis of the light emitting device 15.

Further, the sealing resin 8 may be mixed with a viscosity improver so that the phosphor does not sediment but disperses evenly.

Subsequently, the mold 21 is heated and the sealing resin 8 is subjected to thermal cure. Specifically, the sealing resin 8 is cured for a few minutes in an oven at 80° C. to 150° C. Then, the substrate 1 is separated from the mold 21 and is subjected to an after-cure process under a high temperature condition. Specifically, the substrate 1 is subjected to the after-cure process for approximately 5 hours in an oven at 150° C.

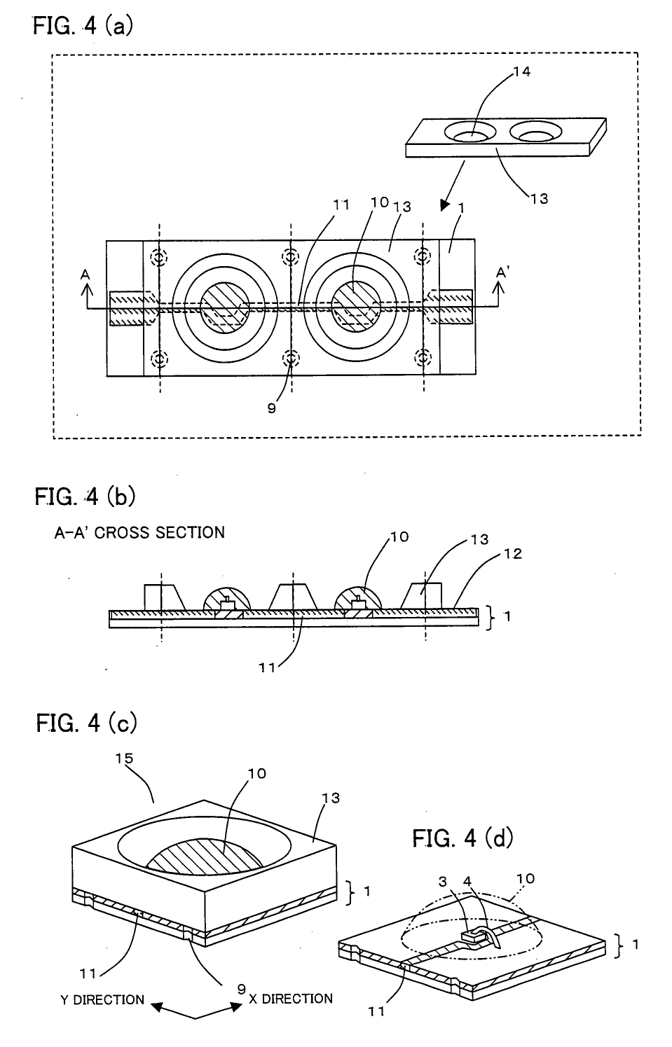

FIGS. 4(a) and 4(b) are a plan drawing and a cross sectional drawing, respectively, of a substrate to which a reflector is attached. FIG. 4(c) is an oblique drawing of a light emitting element obtained by dicing the substrate.

The reflector 13 is a thin plate having a hole 14 formed therein so that a position and an outer diameter of the hole 14 correspond to those of the resin section 10 formed on the main plane 12 of the substrate 1. The vertical cross section of the hole 14 has a mortar shape. The inside of the hole 14 is preferably a reflective surface, which reflects light from the chip 3 and increases a reflective efficiency. The reflector 13 is attached on the main plane 12 of the substrate 1 so that the position of the resin section 10 corresponds to the position of the hole 14.

FIG. 4(d) is an oblique drawing showing the light emitting device 15 from which the reflector 13 is removed for convenience of explanation. As shown in FIG. 4(d), the runner 11 is embedded in the runner section 5 which is a space between wire patterns, and therefore the main plane 12 has an even surface. Consequently, it is possible to attach the reflector 13 without any inclination of the reflector 13.

While the reflector 13 is attached to the main plane 1.2, the reflector 13 surrounds a peripheral part of the resin section 10 at a bottom of the hole 14, allowing light from the chip 3 to be reflected forward.

Lastly, while the reflector 13 is attached to the substrate 1, the substrate 1 is diced at a predetermined position (e.g. at a dotted line), gate sections (including the pouring gate 6 and the exhausting gate 7) which are no longer needed are removed. Thus, the light emitting device 15 is obtained. At that time, the substrate 1 is diced while the runner 11 remains in the runner section 5. Therefore, it is unnecessary to remove the runner 11.

In the present embodiment, one chip 3 is sealed in one resin section 10. Alternatively, a plurality of chips 3 may be sealed in one resin section 10.

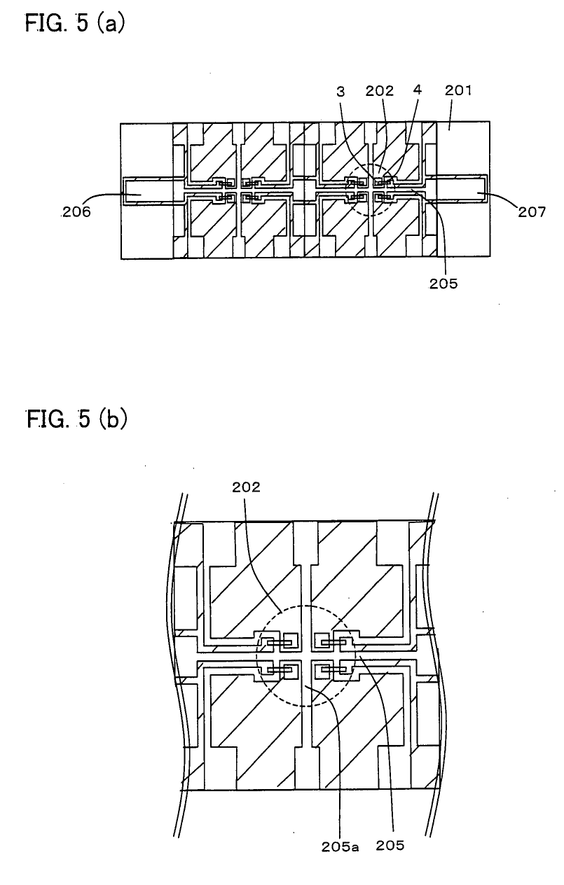

FIG. 5(a) is a plan drawing showing a substrate on which wire patterns are formed so that four chips are sealed in one resin section. FIG. 5(b) is an enlarged plan drawing of sets of the wire drawings.

The wire patterns (indicated by diagonal lines) are separated from one another at (i) a main runner section 205 which is a space between the wire patterns and (ii) a plurality of sub runner sections 205a which branches away from the main runner section 205.

Plural sets of wire patterns 202 are serially formed in one direction on a surface of a substrate 201 so that runner sections 205 are connected with each other.

Both ends of the main runner section 205 are closed. One end is a pouring gate 206 and the other end is an exhausting gate 207.

A plurality of cavities 23 are connected with each other via the main runner section 205 while the substrate 201 is set to a mold 21. The cavities 23 are serially filled with the sealing resin 8 poured from the pouring gate 206. A part of the sealing resin 8 flows into the sub runner section 205a. The sub runner section 205a is merely a space between the wire patterns, and therefore the sub runner section 205a is not necessarily to be filled with the sealing resin 8. For that reason, an end of the sub runner section 205a may be closed or may be open.

As described above, four chips 3 may be sealed in one resin section 10.

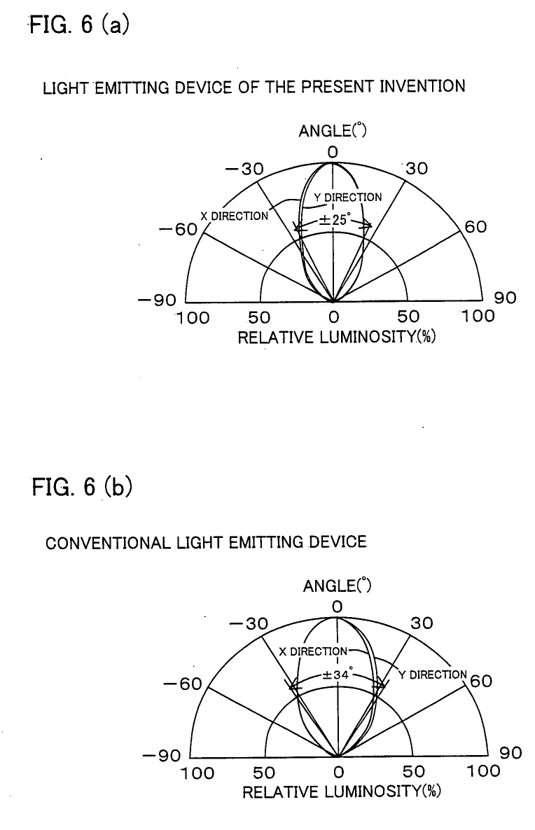

FIGS. 6(a) and 6(b) are drawings showing radiation characteristics of light emitting devices. FIG. 6(a) shows radiation characteristics of a light emitting device of the present embodiment in which a lens is formed integrally with the resin section 10, which device has an outward shown in FIG. 4(c). A radiation angle of the light emitting device is approximately ±25°.

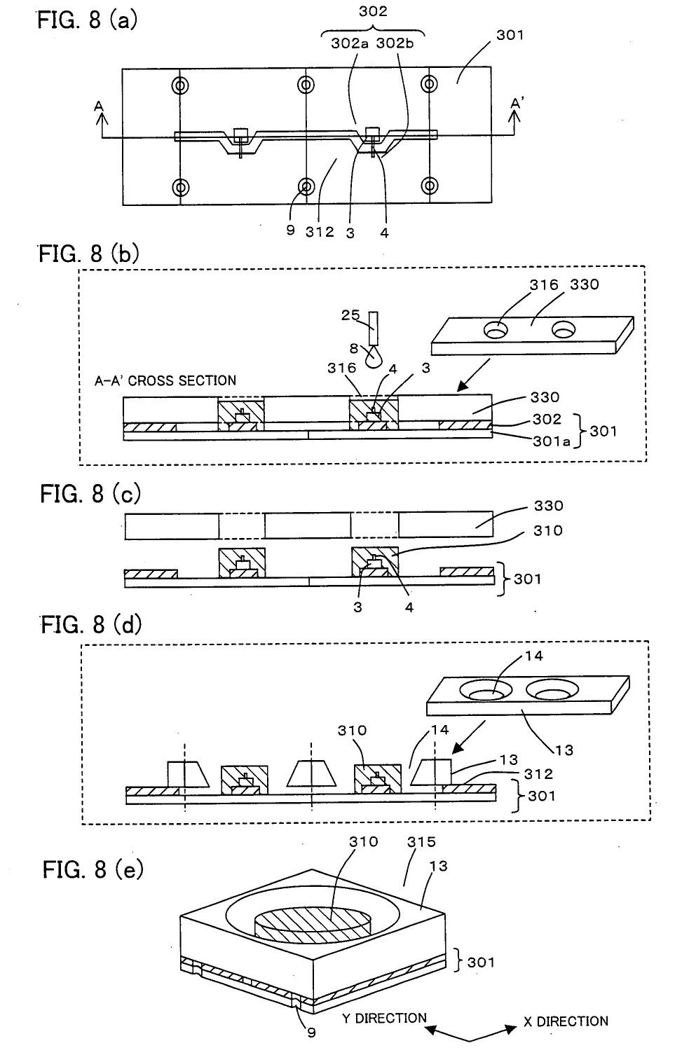

FIG. 6(b) shows radiation characteristics of a conventional light emitting device in which the resin section 310 is formed so as to have a cylindrical shape, which device has an outward shown in FIG. 8(e). A radiation angle of the light emitting device is approximately ±34°. Note that, the x direction and the y direction in which radiation characteristics of the light emitting devices are scanned in FIGS. 6(a) and 6(b) correspond to directions in FIGS. 4(c) and 8(e), respectively.

As described above, a lens is formed integrally with the resin section 10 in the light emitting device of the present embodiment. Consequently, it is possible to make a radiation angle of the light emitting device narrower.

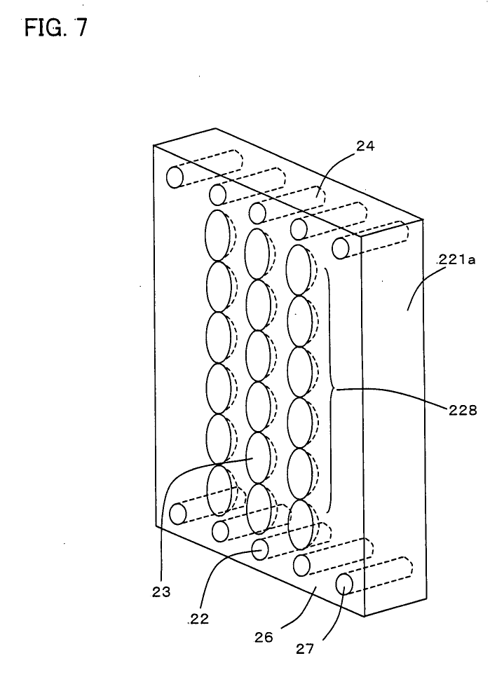

In the present embodiment, the number of the cavities 23 formed in the cavity mold 21a are two. Alternatively, the number may be more than two. Further, cavity lines each including a plurality of cavities 23 provided in one direction may be formed so as to be parallel to one another. For example, as shown in FIG. 7, the cavity lines 228 may be formed in a cavity mold 221a so as to be parallel to one another.

With the present invention, it is possible to produce, with a simple mold, a light emitting device in which a lens is formed integrally with a resin section.

As described above, a light emitting device of the present invention includes: a substrate, including (i) wire patterns separated from each other on a main plane of a basic material, and (ii) a runner made of resin, provided in a space between the wire patterns; and a light emitting element, die-bonded on the substrate, the light emitting element being sealed by the resin constituting the runner. Therefore, the shape of the sealing resin is not limited to a lens shape. The shape of the sealing resin can be changed freely in accordance with the mold.

It is preferable to arrange the light emitting device of the present invention so that surfaces of the wire patterns and a surface of the runner have a same surface level on the main plane.

It is preferable to arrange the light emitting device of the present invention so that a lens is formed integrally with a resin section in which the light emitting element is sealed by the resin.

It is preferable to arrange the light emitting device of the present invention so that a reflector is provided on the main plane.

A method of the present invention for producing a light emitting device includes the steps of: (I) attaching a substrate to a mold which includes a cavity section, a resin pouring port connected with the cavity section, and an air vent open to air, said substrate including, on a main plane thereof, (i) a light emitting element die-bonded on the main plane, (ii) wire patterns separated from each other, and (iii) a runner section to which resin is poured, which runner section is a space between the wire patterns; and (II) pouring resin into the cavity section using the runner section as a path via which the resin flows.

It is preferable to arrange the method of the present invention so that the cavity section includes a plurality of cavities which are provided in one direction and are connected with each other via the runner section.

It is preferable to arrange the method of the present invention so that at least in the step (II), the mold is turned so that the runner section is inclined and the resin is poured from a lower portion to an upper portion of the runner section.

It is preferable to arrange the method of the present invention so that after the step (II), the mold is turned so that the runner section is positioned horizontally.

It is preferable to arrange the method of the present invention so that the resin is poured into the cavities and then the substrate is diced with respect to each cavity, so that a light emitting device is provided.

A substrate of the present invention, on which substrate a light emitting element is to be mounted, includes: wire patterns separated from each other on a surface of a basic material; and a runner section to which resin is poured, said runner section being a space between the wire patterns.

In the light emitting device of the present invention, a space between the wire patterns and a thickness of each wire pattern constitute the runner section having a groove shape, and sealing resin is caused to fill the runner section so as to be a runner. Consequently, the runner does not remain on a side of the resin section. As a result, the main plane is formed evenly, and therefore it is easy to provide a reflector on the main plane. Further, the sealing resin is caused to fill the runner section so as to be a runner and the runner does not need to be removed. Therefore, it is possible to prevent problems in the conventional technique, such as a leakage of light from a part where a runner has been removed and disturbance of radiation characteristics.

Further, in particular, by forming a lens integrally with the resin section, it is possible to converge light emission of a chip.

Further, with the method of the present invention, the surfaces of the wire patterns and the surface of the runner have the same surface level, and the runner formed by filling the runner section with the sealing resin does not need to be removed. Consequently, a process for removing the runner is not required, allowing a process for producing a light emitting device to be simpler.

Further, in particular, the cavity section includes a plurality of cavities which are provided in one direction and are connected with the runner section. Consequently, it is possible to mass-produce light emitting devices at a time.

Further, at least in the step of pouring the sealing resin, the mold is turned so that the runner section is inclined and the sealing resin is poured from the lower portion to the upper portion of the runner section. Consequently, the sealing resin flows so that air remaining in the cavity is caused to move from the lower portion to the upper portion. This allows for preventing bubbles.

Further, after the step of pouring the sealing resin, the mold may be turned so that the runner section is positioned horizontally. As a result, it is possible to prevent phosphor from sedimenting unevenly with respect to an optical axis of the light emitting device and from causing unevenness in color of emitted light, when the phosphor is mixed with the sealing resin.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A light emitting device, comprising:
a substrate, including (i) wire patterns separated from each other on a main plane of a basic material, and (ii) a runner made of resin, provided in a space between the wire patterns; and
a light emitting element, die-bonded on the substrate,
the light emitting element being sealed by the resin constituting the runner.

2. The light emitting device as set forth in claim 1, wherein surfaces of the wire patterns and a surface of the runner have a same surface level on the main plane.

3. The light emitting device as set forth in claim 1, wherein a lens is formed integrally with a resin section in which the light emitting element is sealed by the resin.

4. The light emitting device as set forth in claim 1, wherein a reflector is provided on the main plane.

5. A method for producing a light emitting device, comprising the steps of:
(I) attaching a substrate to a mold which includes a cavity section, a resin pouring port connected with the cavity section, and an air vent open to air, said substrate including, on a main plane thereof, (i) a light emitting element die-bonded on the main plane, (ii) wire patterns separated from each other, and (iii) a runner section to which resin is poured, which runner section is a space between the wire patterns; and
(II) pouring resin into the cavity section using the runner section as a path via which the resin flows.

6. The method as set forth in claim 5, wherein the cavity section includes a plurality of cavities which are provided in one direction and are connected with each other via the runner section.

7. The method as set forth in claim 5, wherein at least in the step (II), the mold is turned so that the runner section is inclined and the resin is poured from a lower portion to an upper portion of the runner section.

8. The method as set forth in claim 7, wherein after the step (II), the mold is turned so that the runner section is positioned horizontally.

9. The method as set forth in claim 6, wherein the resin is poured into the cavities and then the substrate is diced with respect to each cavity, so that a light emitting device is provided.

10. A substrate on which a light emitting element is to be mounted, comprising:
wire patterns separated from each other on a surface of a basic material; and
a runner section to which resin is poured, said runner section being a space between the wire patterns.
